(19) United States
(12) Patent Application Publication
(10) Pub. No.: US 2026/0271215 A1
(43) Pub. Date: Sep. 10, 2026

(54) CHASSIS AND SERVER

(71) Applicants: INVENTEC (PUDONG) TECHNOLOGY CORPORATION, Shanghai (CN); INVENTEC CORPORATION, Taipei City (TW)

(72) Inventor: Chang-Hsin CHIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/453,562

(22) Filed: Jan. 20, 2026

Related U.S. Application Data
(60) Provisional application No. 63/768,321, filed on Mar. 7, 2025.

(30) Foreign Application Priority Data
Jun. 3, 2025 (CN) 202510730032.5

(51) Int. Cl. H05K 7/14

(52) U.S. Cl. CPC H05K 7/1489

(57) ABSTRACT

A chassis includes a bottom plate, two side plates, at least one partition and at least one anti-tilt post. The two side plates protrude from two opposite sides of the bottom plate, respectively. The at least one partition protrudes from the bottom plate, and is located between the two side plates. The at least one partition includes a first plate portion and a second plate portion. The first plate portion contacts the bottom plate. The second plate portion is spaced apart from the bottom plate, and has an assembling hole. The at least one anti-tilt post includes a wide portion and a narrow portion connected to each other. A diameter of the wide portion is greater than a diameter of the narrow portion. The wide portion protrudes from the bottom plate. The narrow portion is inserted into the assembling hole of the second plate portion.

### CROSS-REFERENCE TO RELATED APPLICATIONS

This non-provisional application claims priority under 35 U.S.C. § 119(a) provisional on Provisional Application No(s). 63/768,321 filed in U.S.A. on Mar. 7th, 2025, and Patent Application No(s). 202510730032.5 filed in China, on Jun. 3rd, 2025, the entire contents of which are hereby incorporated by reference.

### BACKGROUND OF THE INVENTION

### Technical Field of the Invention

The invention relates to a chassis and a server, more particularly to a chassis and a server whose anti-tilt post is disposed on a partition thereof.

### Description of the Related Art

With the advancement of technology, the performance of servers has continuously increased. In order to improve the performance of a server, additional electronic components, such as graphics cards or other expansion cards, are increasingly installed in the chassis of the server, and are separated from each other via partitions. However, as the number of electronic components installed in the chassis increases, the structural strengths of the partitions disposed in the chassis may be challenged. The partitions disposed in the chassis are conventionally fixed to the base of the chassis via screws. The lengths of the screws and the number of threads of the screws are limited due to structural constraints of the partitions. As a result, the partitions may have the insufficient resistances to lateral force, which may cause structural instability of the partitions during drop tests. Therefore, how to address the problem of insufficient resistance of the partition to lateral force is one of the topics in this field.

### SUMMARY OF THE INVENTION

The invention provides a chassis and a server which are capable of addressing the problem of insufficient resistance of the partition to lateral force.

One embodiment of the invention provides a chassis including a bottom plate, two side plates, at least one partition and at least one anti-tilt post. The two side plates protrude from two opposite sides of the bottom plate, respectively. The at least one partition protrudes from the bottom plate, and is located between the two side plates. The at least one partition includes a first plate portion and a second plate portion. The first plate portion contacts the bottom plate. The second plate portion is spaced apart from the bottom plate, and has an assembling hole. The at least one anti-tilt post includes a wide portion and a narrow portion connected to each other. A diameter of the wide portion is greater than a diameter of the narrow portion. The wide portion protrudes from the bottom plate. The narrow portion is inserted into the assembling hole of the second plate portion.

Another one embodiment of the invention provides a server including a chassis and an expansion assembly. The chassis includes a bottom plate, two side plates, at least one partition and at least one anti-tilt post. The two side plates protrude from two opposite sides of the bottom plate, respectively. The at least one partition protrudes from the bottom plate, and is located between the two side plates to form an slide channel between the two side plates. The at least one partition includes a first plate portion and a second plate portion. The first plate portion contacts the bottom plate. The second plate portion is spaced apart from the bottom plate, and has an assembling hole. The at least one anti-tilt post includes a wide portion and a narrow portion connected to each other. A diameter of the wide portion is greater than a diameter of the narrow portion. The wide portion protrudes from the bottom plate. The narrow portion is inserted into the assembling hole of the second plate portion. The expansion assembly is slidably disposed in the slide channel.

According to the chassis and the server disclosed in the above embodiments, the chassis additionally includes the anti-tilt posts with the wide portions and the narrow portions, the narrow portions of the anti-tilt posts are respectively inserted into the assembling holes of the second plate portions spaced apart from the bottom plate, and the wide portions of the anti-tilt posts increase the structural strengths of the anti-tilt posts. In such configuration, the anti-tilt posts can enhance the resistance of the second plate portions of the partitions to lateral force. Accordingly, the problem of insufficient resistance of the partitions to lateral force can be addressed.

In addition, since the diameter of the wide portions of the anti-tilt posts are greater than the thicknesses of the partitions, the wide portions of the anti-tilt posts have higher anti-tilt capability than the partitions. Accordingly, the resistance of the partitions to lateral force can be further improved via the wide portions of the anti-tilt posts.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a perspective view showing that a server in accordance with a first embodiment of the invention is placed in a rack;

FIG. 2 is a perspective view of the server in FIG. 1 omitting expansion assemblies;

FIG. 3 is a partial enlarged perspective view of the server in FIG. 2 showing one of partitions and one of anti-tilt posts;

FIG. 4 is a partial side view of the server in FIG. 3 showing the partition and the anti-tilt post of the server;

FIG. 5 is a cross-sectional view of the server in FIG. 3 showing the partition and the anti-tilt post of the server;

FIG. 6 is a perspective view of a server in accordance with a second embodiment of the invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

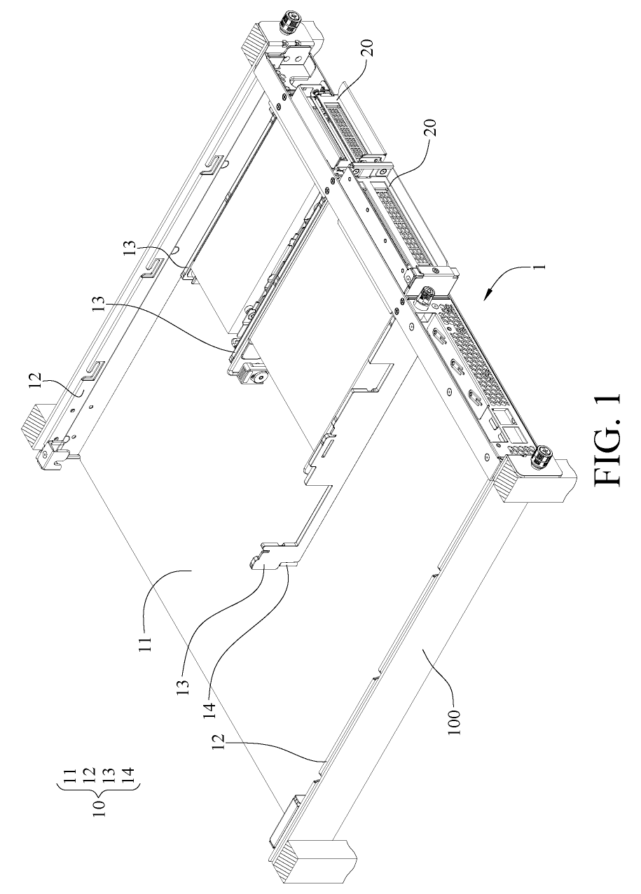

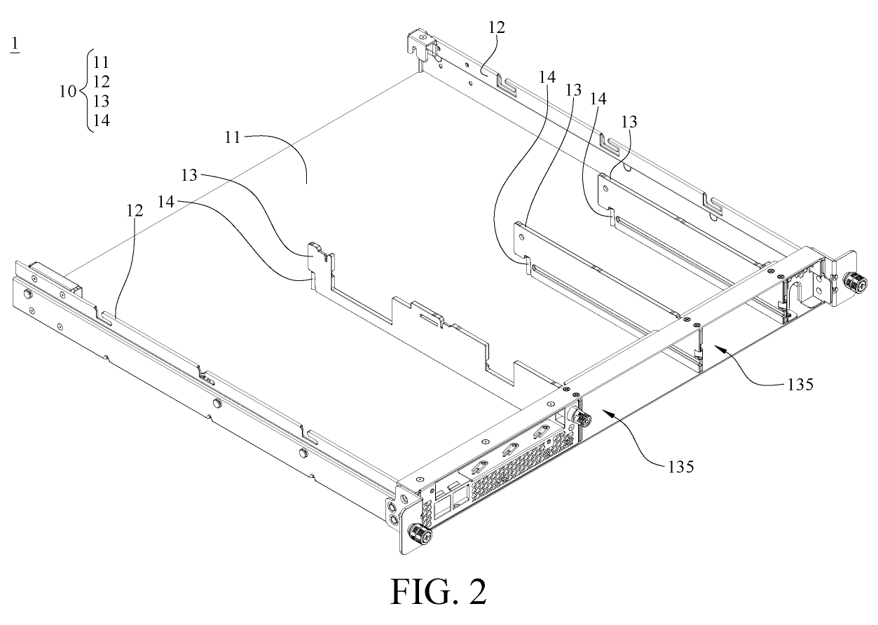

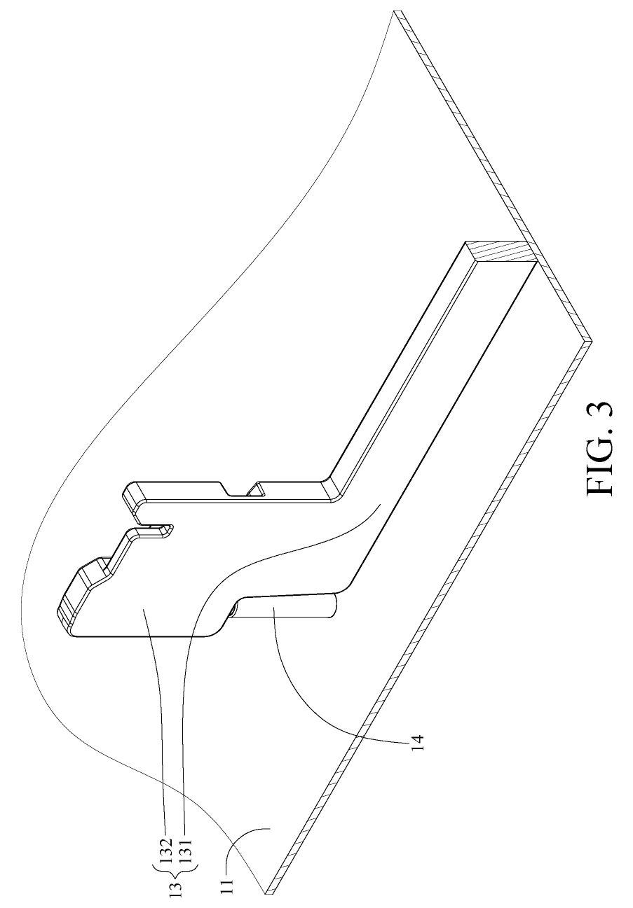

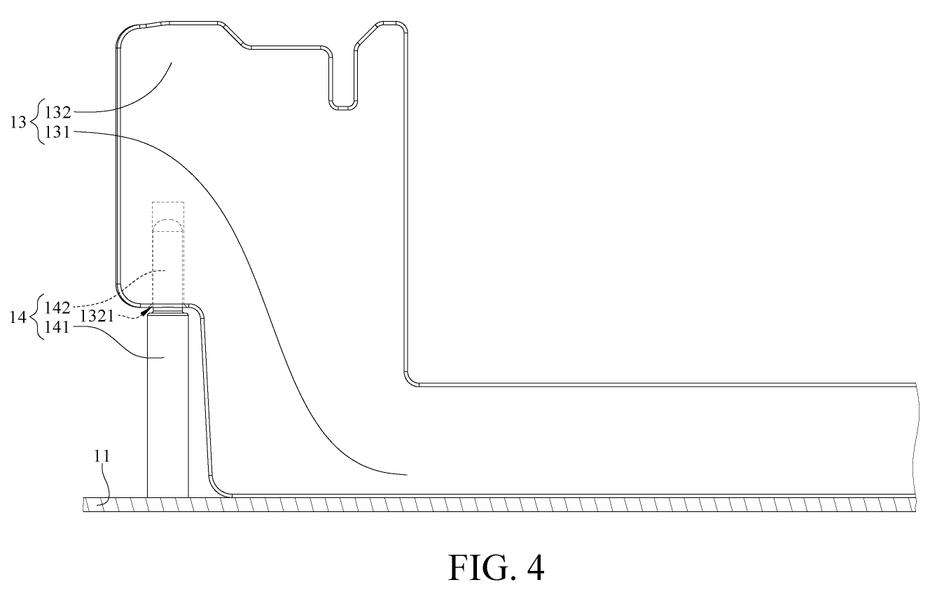

Please refer to FIGS. 1-4, where FIG. 1 is a perspective view showing that a server 1 in accordance with a first embodiment of the invention is placed in a rack 100, FIG. 2 is a perspective view of the server 1 in FIG. 1 omitting expansion assemblies 20, FIG. 3 is a partial enlarged perspective view of the server 1 in FIG. 2 showing one of partitions 13 and one of anti-tilt posts 14, and FIG. 4 is a partial side view of the server 1 in FIG. 3 showing the partition 13 and the anti-tilt post 14 of the server 1. In this embodiment, the server 1 is disposed, for example, in the rack 100, and includes a chassis 10 and a plurality of expansion assemblies 20. The expansion assemblies 20 are, for example, graphics cards.

In this embodiment, the chassis 10 includes a bottom plate 11, two side plates 12, a plurality of partitions 13 and a plurality of anti-tilt posts 14. Heights of the side plates 12 and the partitions 13 are, for example, 1U. The two side plates 12 protrude from two opposite sides of the bottom plate 11, respectively. The partitions 13 are located, for example, on a front side in the chassis 10, but the invention is not limited thereto. The partitions 13 protrude from the bottom plate 11, and are located between the side plates 12. An slide channel 135 is formed between any two adjacent partitions 13.

In this embodiment, the side plates 12 and the bottom plate 11 are, for example, integrally formed as a single piece by bending the same plate. The partitions 13 and the bottom plate 11 are, for example, a plurality of separate components that are not integrally formed and are assembled with each other.

The expansion assemblies 20 are slidably disposed in the slide channels 135, respectively. The anti-tilt posts 14 are disposed on the partitions 13, respectively, to provide the partitions 13 with resistance to lateral force.

In the above embodiment, there are, for example, three partitions 13 and three anti-tilt posts 14. The partitions 13 and the anti-tilt posts 14 correspond to each other by a one-to-one manner, and are divided into multiple groups. Structure and connections between the partitions 13 and the anti-tilt posts 14 in each group are the same or similar. Therefore, only one group of the partition 13 and the anti-tilt post 14 will be described below.

The partition 13 includes a first plate portion 131 and a second plate portion 132. The first plate portion 131 contacts the bottom plate 11, and the second plate portion 132 is spaced apart from the bottom plate 11. That is, a distance between the first plate portion 131 and the bottom plate 11 is different from a distance between the second plate portion 132 and the bottom plate 11.

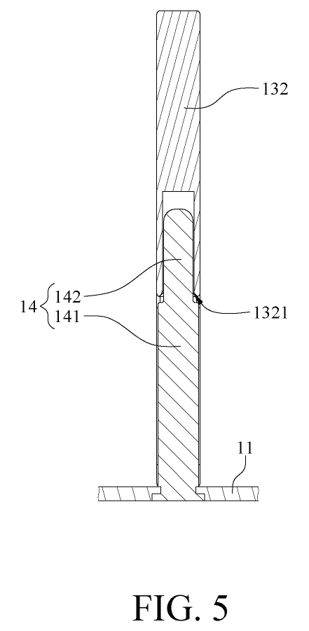

Please refer to FIGS. 1-5, where FIG. 5 is a cross-sectional view of the server 1 in FIG. 3 showing the partition 13 and the anti-tilt post 14 of the server 1. The second plate portion 132 has an assembling hole 1321. The anti-tilt post 14 includes a wide portion 141 and a narrow portion 142 connected to each other. A diameter of the wide portion 141 is greater than a diameter of the narrow portion 142. The wide portion 141 protrudes from the bottom plate 11. The narrow portion 142 is inserted into the assembling hole 1321 of the second plate portion 132. The diameter of the wide portion 141 of the anti-tilt post 14 is, for example, greater than a thickness of the partition 13 to further improve the resistance of the partition 13 to lateral force.

In the above embodiment, the chassis 10 additionally includes the anti-tilt posts 14 with the wide portions 141 and the narrow portions 142, the narrow portions 142 of the anti-tilt posts 14 are respectively inserted into the assembling holes 1321 of the second plate portions 132 spaced apart from the bottom plate 11, and the wide portions 141 of the anti-tilt posts 14 increase the structural strengths of the anti-tilt posts 14. In such configuration, the anti-tilt posts 14 can enhance the resistance of the second plate portions 132 of the partitions 13 to lateral force. Accordingly, the problem of insufficient resistance of the partitions 13 to lateral force can be addressed.

In addition, since the diameter of the wide portions 141 of the anti-tilt posts 14 are greater than the thicknesses of the partitions 13, the wide portions 141 of the anti-tilt posts 14 have higher anti-tilt capability than the partitions 13. Accordingly, the resistance of the partitions 13 to lateral force can be further improved via the wide portions 141 of the anti-tilt posts 14.

In the above embodiment, there are three partitions 13 and three anti-tilt posts 14, but the invention is not limited thereto. In other embodiments, there may be less than three or more than three partitions, and there may be less than three or more than three anti-tilt posts.

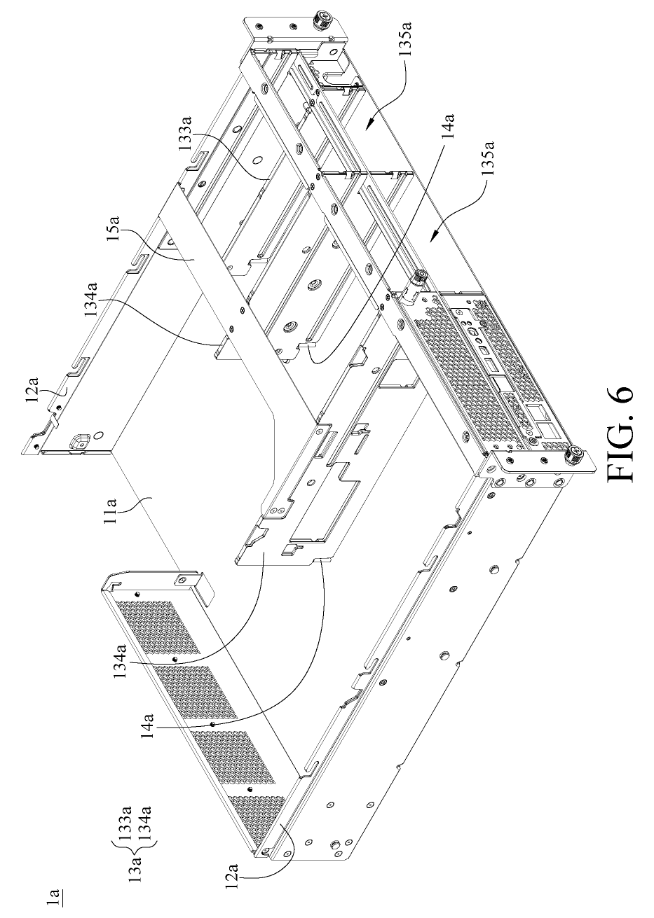

In the above embodiment, the heights of the side plates 12 and the partitions 13 are 1U, but the invention is not limited thereto. In other embodiments, please refer to FIG. 6, which is a perspective view of a server 1a in accordance with a second embodiment of the invention. In this embodiment, the chassis 10a includes a bottom plate 11a, two side plates 12a, a plurality of partitions 13a and a plurality of anti-tilt posts 14a. The two side plates 12a protrude from two opposite sides of the bottom plate 11a, respectively, and the side plates 12a and the bottom plate 11a are, for example, integrally formed as a single piece by bending the same plate. The partitions 13a protrude from the bottom plate 11a, and are located between the side plates 12a. The partitions 13a and the bottom plate 11a are, for example, a plurality of separate components that are not integrally formed and are assembled with each other.

Heights of the side plates 12a are, for example, 2U. The partitions 13a include a first partition 133a and a plurality of second partitions 134a. A height of the first partition 133a is, for example, 1U, and heights of the second partitions 134a are, for example, 2U. That is, the heights of the second partitions 134a are greater than the height of the first partition 133a.

The chassis 10a further includes a reinforcing cover 15a. The reinforcing cover 15a extends across and over the second partitions 134a and one of the side plates 12a, and is fixed to sides of the second partitions 134a and the side plate 12a located farther away from the bottom plate 11a. Generally, the second partitions 134a having greater height may have the insufficient resistance to lateral force. The side plates 12a and the bottom plate 11a are integrally formed as a single piece to provide the high anti-tilt capability, and the reinforcing cover 15a can further enhance the anti-tilt capability of the second partitions 134a via the side plates 12a and the bottom plate 11a integrally formed as a single piece. That is, in addition to supporting the second partitions 134a having greater height via the anti-tilt posts 14a, the structural stability of the second partitions 134a can be further improved via the reinforcing cover 15a additionally. When the second partitions 134a are subjected to the lateral force, the reinforcing cover 15a can share the lateral force. Accordingly, the anti-tilt capability of the taller second partitions 134a can be enhanced.

According to the chassis and the server disclosed in the above embodiments, the chassis additionally includes the anti-tilt posts with the wide portions and the narrow portions, the narrow portions of the anti-tilt posts are respectively inserted into the assembling holes of the second plate portions spaced apart from the bottom plate, and the wide portions of the anti-tilt posts increase the structural strengths of the anti-tilt posts. In such configuration, the anti-tilt posts can enhance the resistance of the second plate portions of the partitions to lateral force. Accordingly, the problem of insufficient resistance of the partitions to lateral force can be addressed.

In addition, since the diameter of the wide portions of the anti-tilt posts are greater than the thicknesses of the partitions, the wide portions of the anti-tilt posts have higher anti-tilt capability than the partitions. Accordingly, the resistance of the partitions to lateral force can be further improved via the wide portions of the anti-tilt posts.

Moreover, since the reinforcing cover connected to the side plates is additionally disposed on a side of the second partitions having greater height located farther away from the bottom plate, the second partitions having greater height can be supported via the reinforcing cover additionally. When the second partitions are subjected to the lateral force, the reinforcing cover can share the lateral force. Accordingly, the structural stability of the taller second partitions can be further improved via the reinforcing cover to enhance the anti-tilt capability of the taller second partitions, thereby addressing the problem of insufficient resistance of the partitions to lateral force.

In this embodiment, the server of the invention can apply artificial intelligence (AI) computing, edge computing, and can also be used as a 5G server, a cloud server or a Vehicle-to-everything server.

It will be apparent to those skilled in the art that various modifications and variations can be made to the invention. It is intended that the specification and examples be considered as exemplary embodiments only, with the scope of the invention being indicated by the following claims.

What is claimed is:

1. A chassis, comprising:
a bottom plate;
two side plates, protruding from two opposite sides of the bottom plate, respectively;
at least one partition, protruding from the bottom plate and located between the two side plates, wherein the at least one partition comprises a first plate portion and a second plate portion, the first plate portion contacts the bottom plate, the second plate portion is spaced apart from the bottom plate, and has an assembling hole; and
at least one anti-tilt post, comprising a wide portion and a narrow portion connected to each other, wherein a diameter of the wide portion is greater than a diameter of the narrow portion, the wide portion protrudes from the bottom plate, and the narrow portion is inserted into the assembling hole of the second plate portion.

2. The chassis according to claim 1, wherein the diameter of the wide portion of the at least one anti-tilt post is greater than a thickness of the at least one partition.

3. The chassis according to claim 1, wherein a height of the two side plates is 1U, the at least one partition comprises a plurality of partitions, and heights of the plurality of partitions are 1U.

4. The chassis according to claim 1, wherein height of the two side plates are 2U, the at least one partition comprises a first partition and a second partition, a height of the first partition is 1U, and a height of the second partition is 2U.

5. The chassis according to claim 4, further comprising a reinforcing cover, wherein the reinforcing cover extends across and over the second partition and one of the two side plates, and the reinforcing cover is fixed to sides of the second partition and the side plate located farther away from the bottom plate.

6. A server, comprising:
a chassis, comprising:
a bottom plate;
two side plates, protruding from two opposite sides of the bottom plate, respectively;
at least one partition, protruding from the bottom plate and located between the two side plates to form an slide channel between the two side plates, wherein the at least one partition comprises a first plate portion and a second plate portion, the first plate portion contacts the bottom plate, the second plate portion is spaced apart from the bottom plate, and has an assembling hole; and
at least one anti-tilt post, comprising a wide portion and a narrow portion connected to each other, wherein a diameter of the wide portion is greater than a diameter of the narrow portion, the wide portion protrudes from the bottom plate, and the narrow portion is inserted into the assembling hole of the second plate portion; and
an expansion assembly, slidably disposed in the slide channel.

7. The server according to claim 6, wherein the diameter of the wide portion of the at least one anti-tilt post is greater than a thickness of the at least one partition.

8. The server according to claim 6, wherein a height of the two side plates is 1U, the at least one partition comprises a plurality of partitions, and height of the plurality of partitions are 1U.

9. The server according to claim 6, wherein height of the two side plates are 2U, the at least one partition comprises a first partition and a second partition, a height of the first partition is 1U, and a height of the second partition is 2U.

10. The server according to claim 9, wherein the chassis further comprises a reinforcing cover, the reinforcing cover extends across and over the second partition and one of the two side plates, and the reinforcing cover is fixed to sides of the second partition and the side plate located farther away from the bottom plate.
